(19) United States
(12) Patent Application Publication
(10) Pub. No.: US 2004/0136476 A1
(43) Pub. Date: Jul. 15, 2004

(54) Method and apparatus for compressing header information for short data burst messaging

(76) Inventors: Eric C. Rosen, Solana Beach, CA (US); Kirti Gupta, San Diego, CA (US)

Correspondence Address: Qualcomm Incorporated, Patents Department, 5775 Morehouse Drive, San Diego, CA, 92121-1714, US

(21) Appl. No.: 10/340,106

(22) Filed: Jan. 10, 2003

(51) Int. Cl. H04B 1/66; H03D 1/00

(52) U.S. Cl. 375/340

(57) ABSTRACT

Methods and apparatus for sending information to a target mobile station include compressing the header portion of short data burst messages before being sent to the target mobile stations, and decompressing the header portion of the received short data burst messages at the mobile stations.

### FIELD

The present invention relates to communicating information in a global distributed network, such as the Internet. More specifically, the present invention relates to methods and apparatus for compressing header information for short data burst messaging, when the packet data communication is in dormant mode.

### BACKGROUND

When an Internet protocol (IP) datagram carrying information destined for a target communication device is sent from a packet data service nodes (PDSNs) to a base station controller/packet control function (BSC/PCF) while the packet session is in dormant, the BSC/PCF may send the information as short data bursts (SDBs). That is, when the received information is determined to be sent as SDB messages, the information may be sent to the target mobile station as SDB over the forward common channel, for example, without waiting for the traffic channel to be activated. Otherwise, traffic channel needs to be re-established before sending the information.

One algorithm is to send the received information to the target mobile station as received from the PDSN. However, the header part of the SDB messages includes a large overhead part, sometimes up to 40 bytes, which reduces the capacity for IP payload in the SDB messages. This becomes especially important for applications that require frequent and small number of messages, such as in voice over IP (VoIP) applications. In VoIP applications, such as group call services or push-to-talk (PTT) applications, which suffer from long communication delays, large headers introduce even larger delays. Furthermore, the large size of the header increases the chance of packet loss due to air-link error.

There is a need, therefore, for mechanisms to compress and/or decompress the header parts of the SDB messages such that the above problems are resolved.

### SUMMARY

The disclosed embodiments provide novel and improved methods and apparatus for compressing the header parts of short data burst messages. The method includes receiving an information packet, determining whether the received information packet belongs to a known session, and compressing the received information packet if the received information packet belongs to a known session.

The disclosed embodiments further provide novel and improved methods and apparatus for decompressing the header parts of short data burst messages. The method includes receiving an information packet and determining whether the received information packet belongs to a known session. If the received information packet belongs to the known session, the method further includes determining whether the received information packet is compressed and, if the received information packet is compressed, decompressing the received information packet.

In another aspect, an apparatus for compressing and/or decompressing header parts of the SDB messages includes a memory unit, a receiver, a transmitter, and a processor communicatively coupled with the memory unit, the receiver, and the transmitter. The processor is capable of executing instructions to carry out the above-mentioned methods.

### BRIEF DESCRIPTION OF THE DRAWINGS

The features and advantages of the present invention will become more apparent from the detailed description of disclosed embodiments set forth below when taken in conjunction with the drawings, and wherein:

FIG. 1 illustrates a call-flow diagram for delivering mobile-terminated short data bursts;

FIG. 2 illustrates SDB messages before and after header compression;

FIG. 3 illustrates an embodiment for a base station controller and a mobile station;

FIG. 4 illustrates a stateful header-compression process;

FIG. 5 illustrates a stateful header-decompression process;

FIG. 6 illustrates a stateless header-compression process; and

FIG. 7 illustrates a stateless header-decompression process.

### DETAILED DESCRIPTION

Before several embodiments are explained in detail, it is to be understood that the scope of the invention should not be limited to the details of the construction and the arrangement of the components set forth in the following description or illustrated in the drawings. Also, it is to be understood that the phraseology and terminology used herein is for the purpose of description and should not be regarded as limiting.

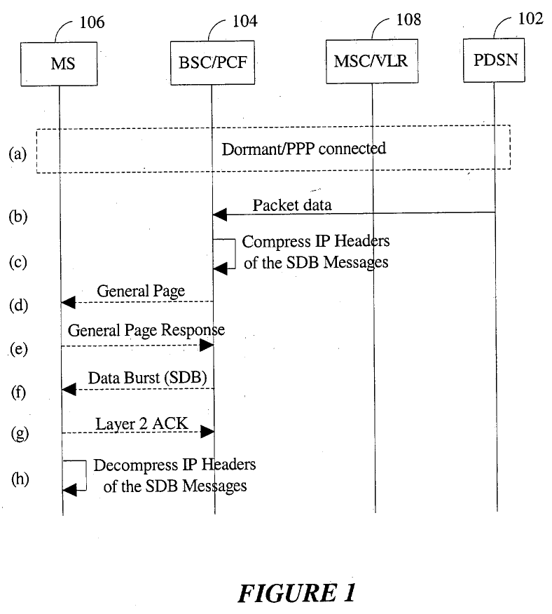

FIG. 1 illustrates a call flow diagram for mobile-terminated short data burst information delivery during dormant packet data session. During dormancy state, the point-to-point protocol (PPP) session is maintained, but traffic channel is deactivated. Information arrived at the PDSN 102, e.g., as IP datagram(s), is sent to BSC/PCF 104, in step (b). BSC/PCF 104 then compresses the IP headers of the SDB messages, in step (c). BSC/PCF 104 uses steps (d) through (g) to deliver the information as SDB. BSC/PCF 104 first performs a general page, in step (d), to locate the target mobile station. Subsequently, the information is sent as SDB over the common channel, for example, to the mobile station (MS) 106, in step (f). The target mobile station may be identified in the mobile's general page response message received in step (e). In step h, the target mobile station decompresses the received SDB, if necessary.

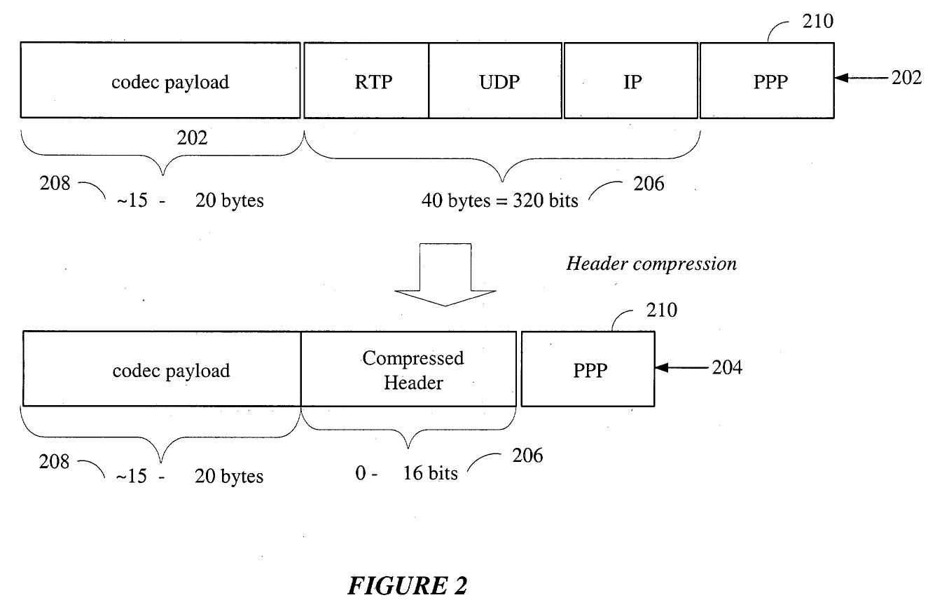

Information destined for the target MS 106 arrives at the PDSN 102 as an IP datagram as shown in FIG. 1. FIG. 2 illustrates an uncompressed SDB message 202 and a compressed SDB message 204, according to one embodiment. A short data burst 202, 204 includes a header part 206, a payload part 208, and a PPP part 210. The header part of the SDB message 202 may include IP, UDP, and RTP sections, taking up to 320 bits, for example. After header compression, the header part may be compressed to take as few as 0-16 bits, for example.

According to one embodiment, as described in TIA/EIA/IS-2001, “Interoperability Specification (IOS) for cdma2000 Access Network Interfaces,” August 2001, (IOSv4.1), before sending the information to the BSC/PCF 104, PDSN 102 adds generic routing encapsulation to the received SDB message 202, 204, forming a PPP frame. The PPP frame is treated as an IP payload and is addressed to the BSC/PCF 104 on an A10 connection, for example. Header compression uses the redundancy between header field values within SDB messages as well as redundancy between consecutive SDB messages belonging to the same information packet stream.

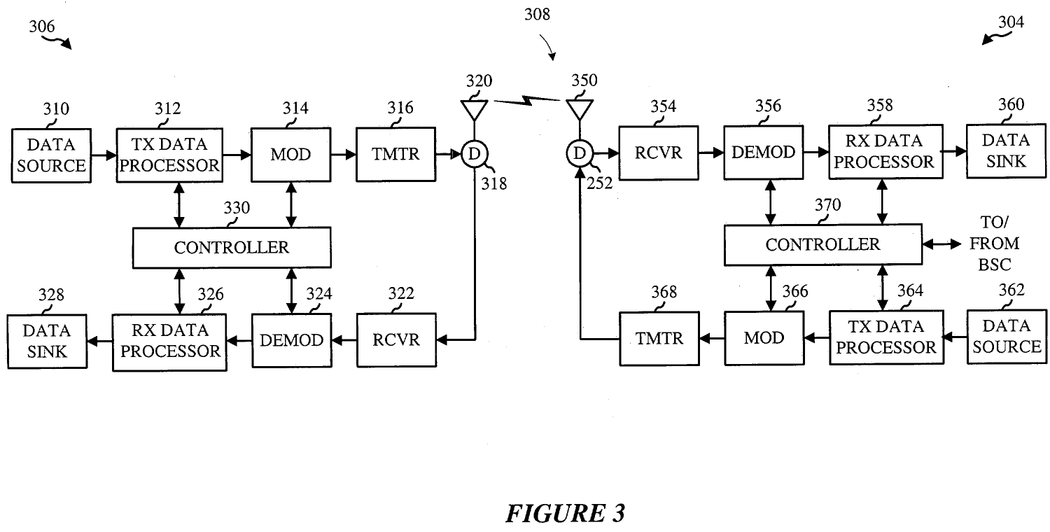

FIG. 3 is a simplified block diagram of an embodiment of a BSC/PCF 304 and mobile station 306, which are capable of implementing various disclosed embodiments. For a particular communication, voice data, packet data, and/or messages may be exchanged between BSC/PCF 304 and mobile station 306, via an air interface 308. Various types of messages may be transmitted, such as messages used to establish a communication session between the BSC/PCF 304 and mobile station 306, registration and paging messages, and messages used to control a data transmission (e.g., power control, data rate information, acknowledgment, and so on). Some of these message types are described in further detail below.

For the reverse link, at BSC/PCF 306, voice and/or packet data (e.g., from a data source 310) and messages (e.g., from a controller 330) are provided to a transmit (TX) data processor 312, which formats and encodes the data and messages with one or more coding schemes to generate coded data. Each coding scheme may include any combination of cyclic redundancy check (CRC), convolutional, turbo, block, and other coding, or no coding at all. The voice data, packet data, and messages may be coded using different schemes, and different types of messages may be coded differently.

The coded data is then provided to a modulator (MOD) 314 and further processed (e.g., covered, spread with short PN sequences, and scrambled with a long PN sequence assigned to the user terminal). The modulated data is then provided to a transmitter unit (TMTR) 316 and conditioned (e.g., converted to one or more analog signals, amplified, filtered, and quadrature modulated) to generate a reverse link signal. The reverse link signal is routed through a duplexer (D) 318 and transmitted via an antenna 320 to BSC/PCF 304.

At BSC/PCF 304, the reverse link signal is received by an antenna 350, routed through a duplexer 352, and provided to a receiver unit (RCVR) 354. BSC/PCF 304 may receive registration information and status information, e.g., mobile station location information, from mobile station 306. Receiver unit 354 conditions (e.g., filters, amplifies, down converts, and digitizes) the received signal and provides samples. A demodulator (DEMOD) 356 receives and processes (e.g., despreads, decovers, and pilot demodulates) the samples to provide recovered symbols. Demodulator 356 may implement a rake receiver that processes multiple instances of the received signal and generates combined symbols. A receive (RX) data processor 358 then decodes the symbols to recover the data and messages transmitted on the reverse link. The recovered voice/packet data is provided to a data sink 360 and the recovered messages may be provided to a controller 370. Controller 370 pages a group of mobile stations, parses the received information packets, and sends SDM messages to the mobile stations. The processing by demodulator 356 and RX data processor 358 are complementary to that performed at mobile station 306. Demodulator 356 and RX data processor 358 may further be operated to process multiple transmissions received via multiple channels, e.g., a reverse fundamental channel (R-FCH) and a reverse supplemental channel (R-SCH). Also, transmissions may be simultaneously from multiple mobile stations, each of which may be transmitting on a reverse fundamental channel, a reverse supplemental channel, or both.

On the forward link, at BSC/PCF 304, voice and/or packet data (e.g., from a data source 362) and messages (e.g., from controller 370) are processed (e.g., formatted and encoded) by a transmit (TX) data processor 364, further processed (e.g., covered and spread) by a modulator (MOD) 366, and conditioned (e.g., converted to analog signals, amplified, filtered, and quadrature modulated) by a transmitter unit (TMTR) 368 to generate a forward link signal. The forward link signal is routed through duplexer 352 and transmitted via antenna 350 to BSC/PCF 306. Forward link signals include paging signals.

At BSC/PCF 306, the forward link signal is received by antenna 220, routed through duplexer 318, and provided to a receiver unit 322. Receiver unit 322 conditions (e.g., down converts, filters, amplifies, quadrature modulates, and digitizes) the received signal and provides samples. The samples are processed (e.g., despreaded, decovered, and pilot demodulated) by a demodulator 324 to provide symbols, and the symbols are further processed (e.g., decoded and checked) by a receive data processor 326 to recover the data and messages transmitted on the forward link. The recovered data is provided to a data sink 328, and the recovered messages may be provided to controller 330. Controller 330 may include instructions for registering BSC/PCF 306, which may be based on the mobility of the mobile station.

Header Compression

A “flow” or an “IP/UDP packet flow” is defined to be a set of information packets or SDB messages passed between two end-points with the same fields, such as source IP address, destination IP address, source UDP port, and destination UDP port. Static fields are the fields that have the same values in subsequent packets belonging to the same flow, such as the IP address port numbers. Dynamic fields are the fields may not have the same values in subsequent packets belonging to the same flow.

The “context” of a compressor is the state the compressor uses to compress a header. The context of the decompressor is the state the decompressor uses to decompress a header portion of a SDB message. Either of these or the two in combination may be referred to as “context”, when it is clear which one is intended. The context contains relevant information from previous headers in the packet stream, such as static fields, and possible reference values for compression and decompression. Moreover, additional information describing the packet stream is also part of the context, for example information about how the IP identifier field changes.

Stateful Header Compression

Stateful or predictive header compression is based on sharing and reusing the “state” in each direction, i.e., at the compressor and the decompressor. A context is established at each end-point for the first packet in a packet stream. The context at the compressor and the context at the decompressor need to be in sync at all times for correct decompression. Both end points update their local context based on the latest packet that has been successfully decompressed.

Stateful compression may be used for streaming similar information packets between two end points, in a bi-directional link. In such cases, the relationship between successive packets in the stream or flow may be exploited to define a shared context or state across the link.

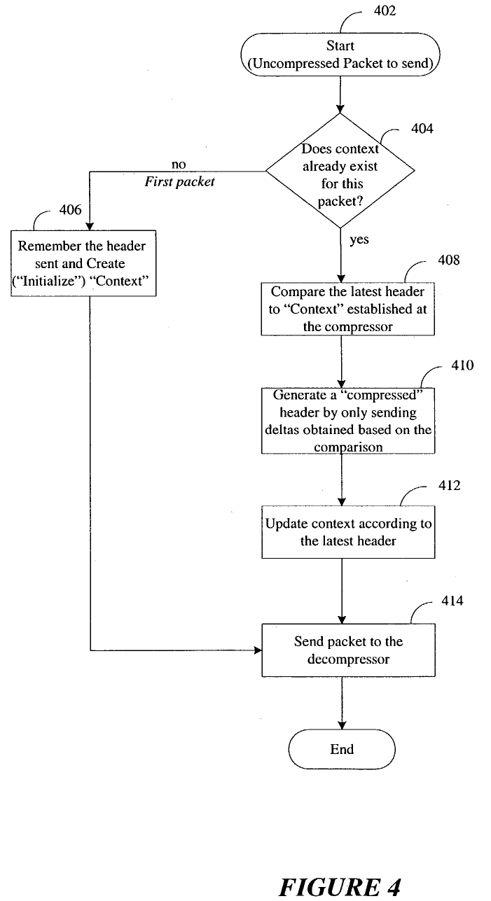

FIG. 4 illustrates a stateful header-compression process, according to one embodiment. Information packets, such as SDB messages, arrive at the compressor, which may be located at the BSC/PCF 104 (FIG. 1), for example. Upon receiving a packet at the compressor, in step 402, the compressor determines, in step 404, whether a context or state already exists for the flow that the received packet belongs to. If no context exists for the received packet, the compressor treats the packet as the first packet of a new flow. In step 406, the compressor remembers the header part of the packet, creates a new context, and sends the packet with full header to the de-compressor, in step 414.

If a context already exists for the received packet, as determined in step 404, the compressor compares, in step 408, the header portion of the received packet with the context already established at the compressor. In step 410, the compressor formulates a compressed header, which may include only the “deltas” or the differential updates based on the received header and the established context. The compressor updates the established context according to the latest received header, in step 412. The compressor then sends the received packet with the compressed header portion to the de-compressor, in step 414.

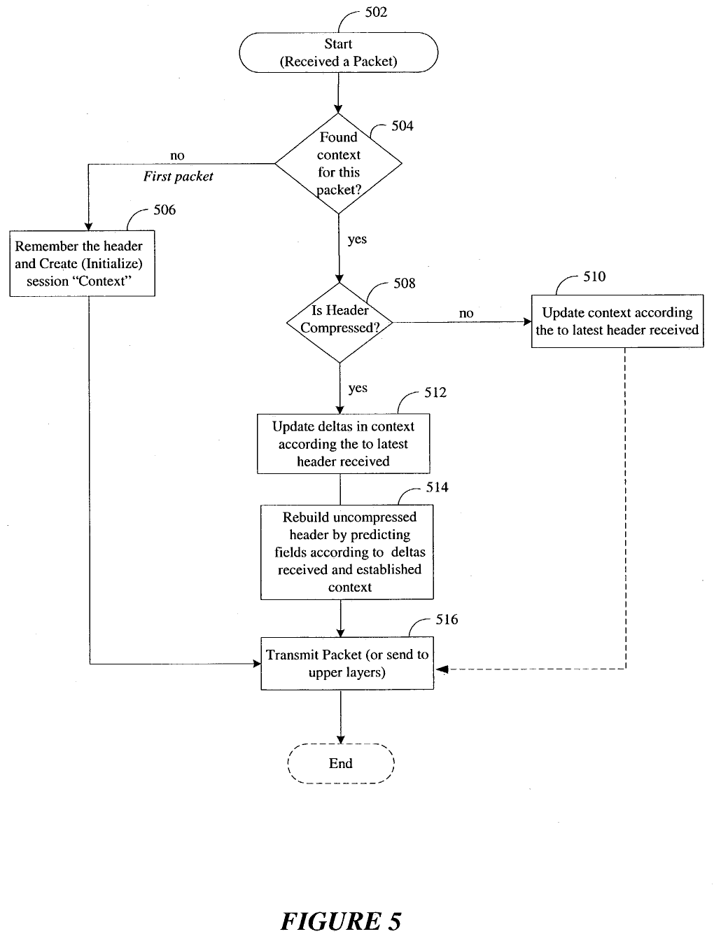

FIG. 5 illustrates a stateful header-decompression process, according to one embodiment. Information packets, with either compressed or uncompressed header, arrive the de-compressor, which may be located at the target mobile station 106 (FIG. 1), for example. Upon receiving a packet at the de-compressor, in step 502, the de-compressor determines, in step 504, whether a context or state already exists for the received packet. If no context is established for the received packet, the de-compressor treats the packet as the first packet belonging to a new flow. In step 506, the de-compressor remembers the header part of the received packet, creates a new flow context; and sends the received packet to the upper layers, in step 514.

If a context already exists for the received packet, as determined in step 504, the de-compressor determines whether the received packet has a compressed header. If the received packet does not have a compressed header, the de-compressor updates the context according to the latest received header, in step 510. The de-compressor then sends the received packet to the upper layers, in step 516. If the received packet has a compressed header portion, as determined in step 508, the de-compressor updates the deltas in the current flow context according to the latest received header.

In step 514, the de-compressor rebuilds an uncompressed header for the received compressed packet based on the deltas received in the compressed header as well as the established current flow context. The compressor then sends the decompressed packet to the upper layers, in step 516.

Stateless Header Compression

Stateless compression does not require establishing or maintaining a context at each end-point. The end points need to remember the most basic state related to each packet flow, i.e., the “static fields.” This state is established upon receiving the first packet, and does not need to be updated for subsequent packets belonging to the same flow. Stateless compression may be used for sending small number of different messages, which may be unrelated in structure, in a unidirectional link. In such cases, little relationship may exist between successive packets; therefore, creating context or state becomes less significant.

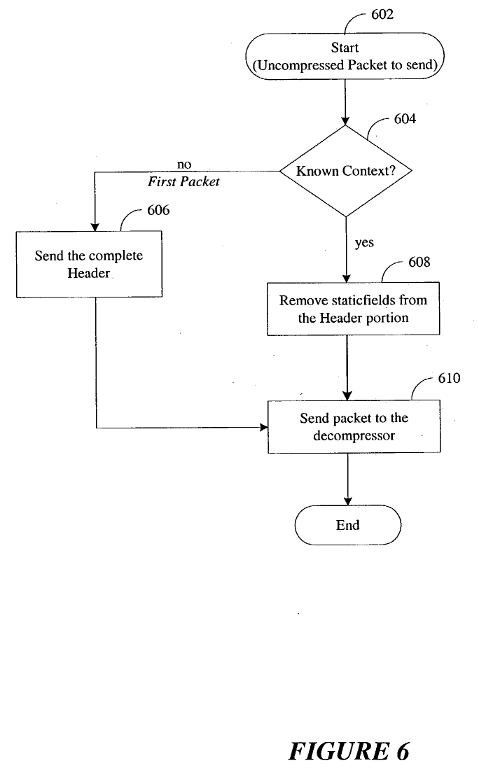

FIG. 6 illustrates a stateless header-compression process, according to one embodiment. Information packets, e.g., SDB messages arrive at the compressor, which may be located at the BSC/PCF 104 (FIG. 1). Upon receiving a packet at the compressor, in step 602, the compressor determines, in step 604, whether a known context exists for the received packet. If no context exists for the received packet, as determined in step 604, the compressor treats the packet as the first packet belonging to a new flow, in step 606, and sends the received packet with the complete header to the de-compressor, in step 614.

If a context already exists for the received packet, as determined in step 604, the compressor removes the static fields from the header and leaves only the dynamic fields in the header part of the received packet. In step 410, the compressor then sends the compressed packet to the de-compressor.

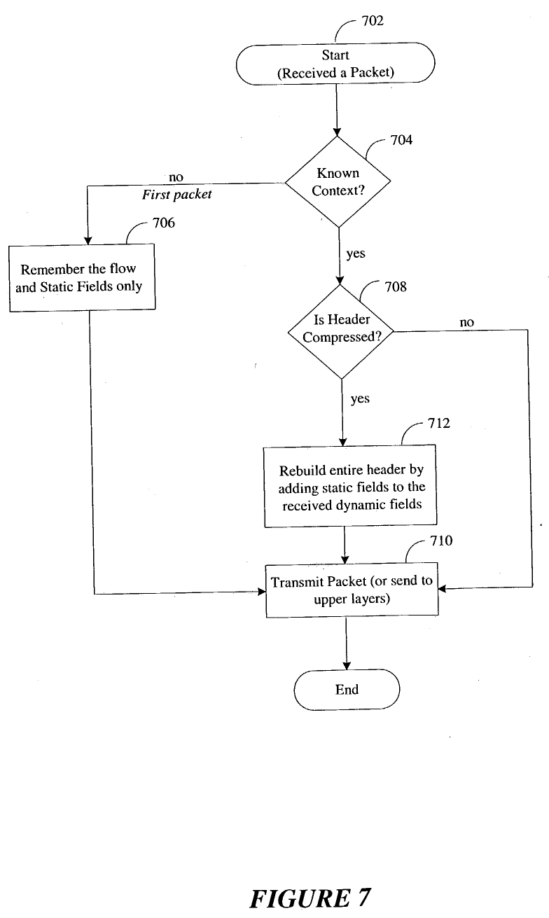

FIG. 7 illustrates a stateless header-decompression process, according to one embodiment. Information packets, e.g., SDB messages, with either compressed or uncompressed header portion, arrive at the de-compressor, which may be located at the target mobile station 106 (FIG. 1), for example. Upon receiving a packet at the decompressor, in step 702, the de-compressor determines, in step 704, whether a known context already exists for the received packet. If no context exists for the received packet, as determined in step 704, the de-compressor treats the packet as the first packet belonging to a new flow. In step 706, the de-compressor remembers the new flow and the static fields within the header portion, and sends the received packet to the upper layers, in step 714.

If a context already exists for the received packet, as determined in step 704, the de-compressor determines whether the received packet is compressed or not, in step 706. If the received packet is not compressed, de-compressor then sends the received packet to the upper layers, in step 710. If the received packet is compressed, as determined in step 708, the de-compressor rebuilds the entire header by adding the static fields to the received dynamic fields in the header portion. The compressor then sends the decompressed packet to the upper layers, in step 710.

Therefore, the disclosed embodiments provide for an efficient and reliable system and method for compressing and decompressing the header part of information packets destined to a target mobile station.

Those of skill in the art would understand that information and signals may be represented using any of a variety of different technologies and protocols. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both.

To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, a hard disk, a removable disk, a CD-ROM, or any other form of storage medium known in the art. An exemplary storage medium is coupled to the processor, such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The description of the disclosed embodiments is provided to enable any person skilled in the art to make or use the present invention. Various modifications to these embodiments may be readily apparent to those skilled in the art, and the generic principles defined herein may be applied to other embodiments, e.g., in an instant messaging service or any general wireless data communication applications, without departing from the spirit or scope of the invention. Thus, the present invention is not intended to be limited to the embodiments shown herein but is to be accorded the widest scope consistent with the principles and novel features disclosed herein. The word “exemplary” is used exclusively herein to mean “serving as an example, instance, or illustration.”

1. A method for compressing information packets, the method comprising:
receiving an information packet;
determining whether the received information packet belongs to a known session;
compressing the received information packet if the received information packet belongs to a known session.

2. The method of claim 1, wherein the information packet includes a header portion and an information portion.

3. The method of claim 2, wherein said compressing includes compressing the header portion.

4. The method of claim 3, wherein said compressing further includes removing a static field from the received header portion.

5. A computer-readable medium embodying a method for compressing information packets, the method comprising:
receiving an information packet;
determining whether the received information packet belongs to a known session;
compressing the received information packet if the received information packet belongs to a known session.

6. The computer-readable medium of claim 5, the information packet includes a header portion and an information portion.

7. The computer-readable medium of claim 6, wherein said compressing includes compressing the header portion.

8. The computer-readable medium of claim 7, wherein said compressing further includes removing a static field from the received header portion.

9. An apparatus for compressing information packets, comprising:
means for receiving an information packet;
means for determining whether the received information packet belongs to a known session;
means for compressing the received information packet if the received information packet belongs to a known session.

10. The apparatus of claim 9, wherein the information packet includes a header portion and an information portion.

11. The apparatus of claim 10, wherein said means for compressing includes means for compressing the header portion.

12. The apparatus of claim 11, wherein said means for compressing further includes means for removing a static field from the received header portion.

13. An apparatus for compressing information packets, comprising:
a receiver capable of receiving information;
a transmitter capable of transmitting information to a target mobile station; and
a processor capable of carrying out a method for compressing information packets, the method comprising:
receiving an information packet;
determining whether the received information packet belongs to a known session; and
compressing the received information packet if the received information packet belongs to a known session.

14. The apparatus of claim 13, wherein the information packet includes a header portion and an information portion.

15. The apparatus of claim 14, wherein said compressing includes compressing the header portion.

16. The apparatus of claim 15, compressing further includes removing a static field from the received header portion.

17. A method for decompressing an information packet, the method comprising: wherein said compressing includes compressing the header portion.
receiving an information packet;
determining whether the received information packet belongs to a known session;
determining whether the received information packet is compressed, if the received information packet belongs to the known session; and
decompressing the received information packet, if the received information packet is compressed.

18. The method of claim 17, wherein the information packet includes a header portion and an information portion.

19. The method of claim 18, wherein said decompressing includes decompressing the header portion.

20. The method of claim 19, wherein said decompressing further includes adding a static field to the received header portion.

21. A computer-readable medium embodying a method for decompressing an information packet, the method comprising:
receiving an information packet;
determining whether the received information packet belongs to a known session;
determining whether the received information packet is compressed, if the received information packet belongs to the known session; and
decompressing the received information packet, if the received information packet is compressed.

22. The computer-readable medium of claim 21, wherein the information packet includes a header portion and an information portion.

23. The computer-readable medium of claim 22, wherein said decompressing includes decompressing the header portion.

24. The computer-readable medium of claim 23, wherein said decompressing further includes adding a static field to the received header portion.

25. An apparatus for decompressing an information packet, comprising:
means for receiving an information packet;
means for determining whether the received information packet belongs to a known session;
means for determining whether the received information packet is compressed, if the received information packet belongs to the known session; and
means for decompressing the received information packet, if the received information packet is compressed.

26. The apparatus of claim 25, wherein the information packet includes a header portion and an information portion.

27. The apparatus of claim 26, wherein said means for decompressing includes means for decompressing the header portion.

28. The apparatus of claim 27, wherein said means for decompressing further includes means for adding a static field to the received header portion.

29. An apparatus for decompressing an information packet, comprising:
a receiver capable of receiving information;
a transmitter capable of transmitting information to a target mobile station; and
a processor capable of carrying out a method for compressing information packets, the method comprising:
receiving an information packet;
determining whether the received information packet belongs to a known session;
determining whether the received information packet is compressed, if the received information packet belongs to the known session; and
decompressing the received information packet, if the received information packet is compressed.

30. The apparatus of claim 29, wherein the information packet includes a header portion and an information portion.

31. The apparatus of claim 30, wherein said decompressing includes decompressing the header portion.

32. The apparatus of claim 31, wherein said decompressing further includes adding a static field to the received header portion.

33. A method for compressing an information packet, comprising:
receiving an information packet;
determining whether a context is established for a flow that the received information packet belongs to; and
compressing the received information packet if the context is established for the flow that the received information packet belongs to.

34. The method of claim 33, wherein the information packet includes a header portion and an information portion.

35. The method of claim 34, wherein said compressing includes:
comparing the header portion of the received information packet with the established context; and
generating a compressed header portion that includes differential values based on said comparison.

36. The method of claim 35, further including updating the established context based on the header portion of the received information packet.

37. A computer-readable medium embodying a method for compressing an information packet, the method comprising:
receiving an information packet;
determining whether a context is established for a flow that the received information packet belongs to; and
compressing the received information packet if the context is established for the flow that the received information packet belongs to.

38. The computer-readable medium of claim 37, wherein the information packet includes a header portion and an information portion.

39. The computer-readable medium of claim 38, wherein said compressing includes:
comparing the header portion of the received information packet with the established context; and
generating a compressed header portion that includes differential values based on said comparison.

40. The computer-readable medium of claim 39, further including updating the established context based on the header portion of the received information packet.

41. An apparatus for compressing an information packet, comprising:
means for receiving an information packet;
means for determining whether a context is established for a flow that the received information packet belongs to; and
means for compressing the received information packet if the context is established for the flow that the received information packet belongs to.

42. The apparatus of claim 41, wherein the information packet includes a header portion and an information portion.

43. The apparatus of claim 42, wherein said means for compressing includes:
means for comparing the header portion of the received information packet with the established context; and
means for generating a compressed header portion that includes differential values based on said comparison.

44. The apparatus of claim 43, further including means for updating the established context based on the header portion of the received information packet.

45. An apparatus for compressing an information packet, comprising:
a receiver capable of receiving information;
a transmitter capable of transmitting information to a target mobile station; and
a processor capable of carrying out a method for compressing information packets, the method comprising:
receiving an information packet;
determining whether a context is established for a flow that the received information packet belongs to; and
compressing the received information packet if the context is established for the flow that the received information packet belongs to.

46. The apparatus of claim 45, wherein the information packet includes a header portion and an information portion.

47. The apparatus of claim 46, wherein said compressing includes:
comparing the header portion of the received information packet with the established context; and
generating a compressed header portion that includes differential values based on said comparison.

48. The apparatus of claim 47, further including updating the established context based on the header portion of the received information packet.

49. A method for decompressing an information packet, the method comprising:
receiving an information packet;
determining whether a context is established for a flow that the received information packet belongs to;
determining whether the received information packet is compressed, if the context is established for the flow that the received information packet belongs to; and
decompressing the received information packet, if the received information packet is compressed.

50. The method of claim 49, wherein the information packet includes a header portion and an information portion, the header portion including differential values.

51. The method of claim 50, further including updating the established context based on the header portion of the received information packet.

52. The method of claim 51, wherein said decompressing includes generating a decompressed header portion based on the differential values and the established context.

53. A computer-readable method for decompressing an information packet, the method comprising:
receiving an information packet;
determining whether a context is established for a flow that the received information packet belongs to;
determining whether the received information packet is compressed, if the context is established for the flow that the received information packet belongs to; and
decompressing the received information packet, if the received information packet is compressed.

54. The computer-readable method of claim 53, wherein the information packet includes a header portion and an information portion, the header portion including differential values.

55. The computer-readable method of claim 54, further including updating the established context based on the header portion of the received information packet.

56. The computer-readable method of claim 55, wherein said decompressing includes generating a decompressed header portion based on the differential values and the established context.

57. An apparatus for decompressing an information packet, comprising:
means for receiving an information packet;
means for determining whether a context is established for a flow that the received information packet belongs to;
means for determining whether the received information packet is compressed, if the context is established for the flow that the received information packet belongs to; and
means for decompressing the received information packet, if the received information packet is compressed.

58. The apparatus of claim 57, wherein the information packet includes a header portion and an information portion, the header portion including differential values.

59. The apparatus of claim 58, further including means for updating the established context based on the header portion of the received information packet.

60. The apparatus of claim 59, wherein said means for decompressing includes means for generating a decompressed header portion based on the differential values and the established context.

61. An apparatus for decompressing an information packet, comprising:
a receiver capable of receiving information;
a transmitter capable of transmitting information to a target mobile station; and
a processor capable of carrying out a method for compressing information packets, the method comprising:
receiving an information packet;
determining whether a context is established for a flow that the received information packet belongs to;
determining whether the received information packet is compressed, if the context is established for the flow that the received information packet belongs to; and
decompressing the received information packet, if the received information packet is compressed.

62. The apparatus of claim 61, wherein the information packet includes a header portion and an information portion, the header portion including differential values.

63. The apparatus of claim 62, further including updating the established context based on the header portion of the received information packet.

64. The apparatus of claim 63, wherein said decompressing includes generating a decompressed header portion based on the differential values and the established context.
